(19) United States
(12) Patent Application Publication
(10) Pub. No.: US 2026/0304716 A1
(43) Pub. Date: Oct. 1, 2026

(54) POWER CONVERSION DEVICE

(71) Applicant: Mitsubishi Electric Mobility Corporation, Tokyo (JP)

(72) Inventors: Katsuyuki OCHIAI, Tokyo (JP); Koji NISHI, Tokyo (JP)

(73) Assignee: Mitsubishi Electric Mobility Corporation, Tokyo (JP)

(21) Appl. No.: 19/490,174

(22) PCT Filed: Oct. 27, 2023
(86) PCT No.: PCT/JP2023/038842

§ 371 Date: Dec. 4, 2025

(51) Int. Cl. H05K 7/20; H02M 7/00

(52) U.S. Cl. CPC H05K 7/20927; H02M 7/003; H05K 7/20272

(57) ABSTRACT

A power conversion device includes: a cooler; one or a plurality of capacitors; one or a plurality of semiconductor modules; and one or a plurality of heat dissipation members including a part integrated with the capacitors, and one or a plurality of connection portions exposed from the capacitors. The one or plurality of connection portions are thermally connected to a first cooling portion. The one or plurality of semiconductor modules are thermally connected to a second cooling portion. The first sectional area which is a sectional area perpendicular to the flow direction in a part of the first passage directly under the one or plurality of connection portions is smaller than the second sectional area which is a sectional area perpendicular to the flow direction in a part of the second passage directly under the one or plurality of semiconductor modules.

### TECHNICAL FIELD

The present disclosure relates to a power conversion device.

### BACKGROUND ART

In an electric vehicle such as an electric car or a hybrid car in which a motor is used as a drive source, a plurality of power conversion devices are provided. Examples of such power conversion devices include a charger which converts commercial AC power to DC power to charge a high-voltage battery, a DC/DC converter which converts DC power of a high-voltage battery to voltage (e.g., 12 V) of a battery for auxiliary equipment, and an inverter which converts DC power from a battery to AC power for a motor.

Among such power conversion devices, there is known a power conversion device that includes a semiconductor module having a switching element for performing power conversion, a cooler for cooling the semiconductor module, and a capacitor for smoothing DC voltage. The power conversion device may be configured to cool a semiconductor module which generates heat, using a coolant. In recent years, as such a power conversion device has an increasingly higher output, not only the semiconductor module but also an electronic component such as a capacitor may need to be cooled. In addition, since the sizes of components increase with output increase, the weight of the power conversion device increases. However, in order to extend the cruising distance of an electric vehicle, the weight of the vehicle needs to be reduced and therefore the weight of the power conversion device is required to be made as small as possible. Therefore, a power conversion device that can cool a semiconductor module and an electronic component effectively while having a cooling structure that is as simple as possible is required.

A configuration of a power conversion device for efficiently cooling a capacitor is proposed (see, for example, Patent Document 1 and Patent Document 2). Patent Document 1 discloses a structure in which a part exposed outside a heat dissipation metal body integrated with a capacitor is thermally connected to a cooler and the capacitor is cooled via the heat dissipation metal body. Patent Document 2 discloses a configuration in which a housing of a power conversion device and a passage through which a coolant flows are integrated. In this configuration, a passage meandering so that the direction in which the coolant flows changes repeatedly is formed under the capacitor, whereby the capacitor is effectively cooled and size increase in the power conversion device is suppressed.

### CITATION LIST

### Patent Document

Patent Document 1: Japanese Patent No. 6,932,225
Patent Document 2: Japanese Laid-Open Patent Publication No. 2022-1602271

### SUMMARY OF THE INVENTION

### Problem to be Solved by the Invention

In Patent Document 1, since the heat dissipation metal body is provided, the capacitor can be cooled via the heat dissipation metal body. When the heat dissipation metal body is provided, cooling routes for the capacitor include mainly two routes, i.e., a route through which heat is dissipated to the cooler from a capacitor case storing a capacitor element, and a route through which heat is dissipated to the cooler from the heat dissipation metal body. The capacitor case and the inner side of the capacitor case are often formed by resin having a small thermal conductivity, or the like. Therefore, the route for heat dissipation to the cooler from the heat dissipation metal body having a great thermal conductivity serves dominantly in heat dissipation of the capacitor. In a case where the cooler has passages, if the area of a passage provided under the heat dissipation metal body is large relative to the area of a part where the heat dissipation metal body is joined to the cooler, passage parts other than the joining part between the heat dissipation metal body and the cooler and a part therearound less contribute to cooling of the capacitor, thus having a problem that the cooling efficiency of the capacitor is reduced.

In Patent Document 2, since the passage meandering so that the direction in which the coolant flows changes repeatedly is formed, the capacitor can be effectively cooled. However, since the housing and the passage are integrally formed, a region where a passage is not necessary also needs to be covered by a passage forming body, to form a passage. Therefore, there is a problem that the weight of the cooling structure increases as compared to a case of forming passages only in necessary regions. In addition, since the passage meandering so that the direction in which the coolant flows changes repeatedly is formed in a region directly under the capacitor, the passage area becomes large, thus having a problem that the weight of the cooling structure increases.

An object of the present disclosure is to provide a power conversion device that has a cooling structure having improved cooling efficiency for a capacitor while suppressing increase in weight.

### Means to Solve the Problem

A power conversion device according to the present disclosure includes: a cooler including a first passage, a second passage, a coolant inlet through which a coolant is supplied to the first passage, and a coolant outlet through which the coolant is discharged from the second passage, such that the coolant supplied from the coolant inlet flows through the first passage and the second passage in this order and then is discharged from the coolant outlet; one or a plurality of capacitors; one or a plurality of semiconductor modules electrically connected to the capacitors; and one or a plurality of heat dissipation members including a part integrated with the capacitors, and one or a plurality of connection portions exposed from the capacitors. The one or plurality of connection portions are thermally connected to a first cooling portion which is a part of a cooling surface made of metal, of the cooler, opposed to the first passage. The one or plurality of semiconductor modules are thermally connected to a second cooling portion which is a part of the cooling surface made of metal, of the cooler, opposed to the second passage. A first sectional area which is a sectional area perpendicular to a flow direction in a part of the first passage directly under the one or plurality of connection portions is smaller than a second sectional area which is a sectional area perpendicular to a flow direction in a part of the second passage directly under the one or plurality of semiconductor modules.

### Effect of the Invention

The power conversion device according to the present disclosure includes: the cooler in which the coolant flows through the first passage and the second passage in this order; the one or plurality of capacitors; the one or plurality of semiconductor modules; and the one or plurality of heat dissipation members including a part integrated with the capacitors, and the one or plurality of connection portions exposed from the capacitors. The one or plurality of connection portions are thermally connected to the first cooling portion which is a part of the cooling surface made of metal, of the cooler, opposed to the first passage. The one or plurality of semiconductor modules are thermally connected to the second cooling portion which is a part of the cooling surface made of metal, of the cooler, opposed to the second passage. The first sectional area which is a sectional area perpendicular to the flow direction in a part of the first passage directly under the one or plurality of connection portions is smaller than the second sectional area which is a sectional area perpendicular to the flow direction in a part of the second passage directly under the one or plurality of semiconductor modules. Thus, the volume of a part that forms the first passage in the cooler can be reduced, whereby increase in the weight of the cooling structure can be suppressed. In addition, since the first sectional area is smaller than the second sectional area, the flow rate of the coolant in the first sectional area region of the first passage increases, whereby cooling efficiency for the connection portion can be improved. Since cooling efficiency for the connection portion is improved, cooling efficiency for the capacitors can be improved.

### BRIEF DESCRIPTION OF THE DRAWINGS

FIG. 1 is a plan view schematically showing a power conversion device according to embodiment 1.

FIG. 2 is a sectional view of the power conversion device taken at an A-A cross-section position in FIG. 1.

FIG. 3 is a sectional view of the power conversion device taken at a B-B cross-section position in FIG. 1.

FIG. 4 is a sectional view of the power conversion device taken at a C-C cross-section position in FIG. 1.

FIG. 5 is a plan view schematically showing another power conversion device according to embodiment 1.

FIG. 6 is a plan view schematically showing a power conversion device according to embodiment 2.

FIG. 7 is a plan view schematically showing another power conversion device according to embodiment 2.

FIG. 8 is a plan view schematically showing another power conversion device according to embodiment 2.

FIG. 9 is a plan view schematically showing a power conversion device according to embodiment 3.

FIG. 10 is a sectional view of the power conversion device taken at a D-D cross-section position in FIG. 9.

FIG. 11 is a plan view schematically showing another power conversion device according to embodiment 3.

FIG. 12 is a plan view schematically showing a power conversion device according to embodiment 4.

FIG. 13 is a plan view schematically showing a power conversion device according to embodiment 5.

FIG. 14 is a plan view schematically showing a power conversion device according to embodiment 6.

FIG. 15 is a sectional view of the power conversion device taken at an E-E cross-section position in FIG. 14.

FIG. 16 is a plan view schematically showing a power conversion device according to embodiment 7.

FIG. 17 is a plan view schematically showing a power conversion device according to embodiment 8.

FIG. 18 is a sectional view schematically showing a power conversion device according to embodiment 9.

FIG. 19 is a plan view schematically showing a power conversion device according to embodiment 10.

FIG. 20 is a sectional view of the power conversion device taken at an F-F cross-section position in FIG. 19.

FIG. 21 shows an example of a placement state of a power conversion device according to embodiment 11.

### DESCRIPTION OF EMBODIMENTS

Hereinafter, a power conversion device according to embodiments of the present disclosure will be described with reference to the drawings. In the drawings, the same or corresponding members and parts are denoted by the same reference characters to give description.

### Embodiment 1

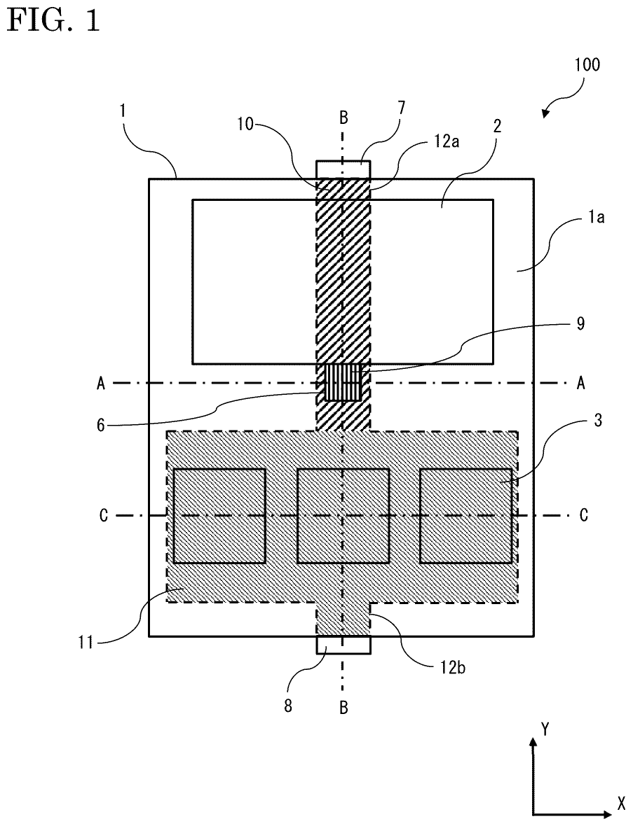

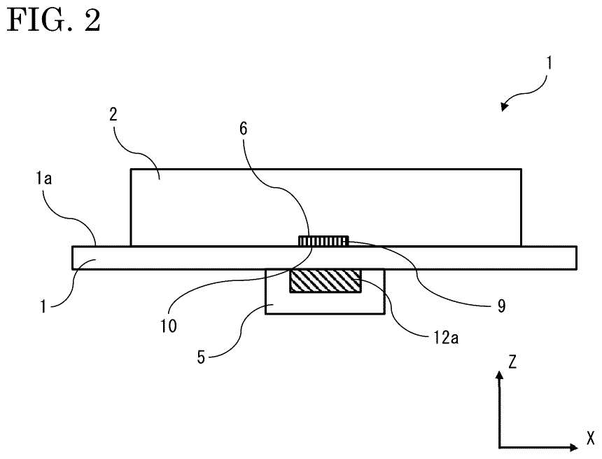

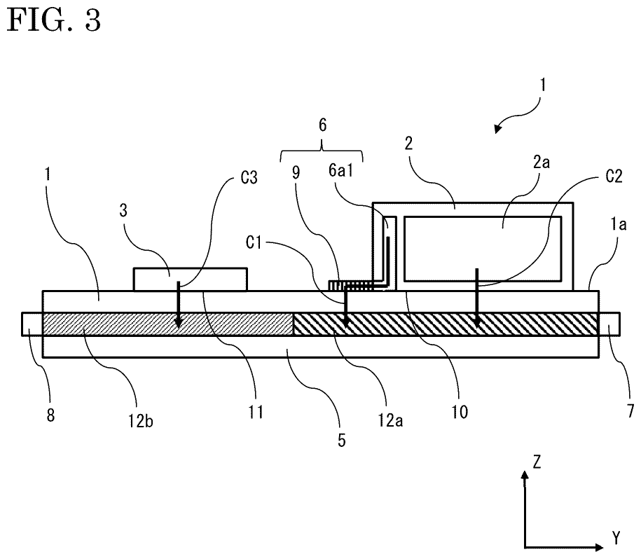

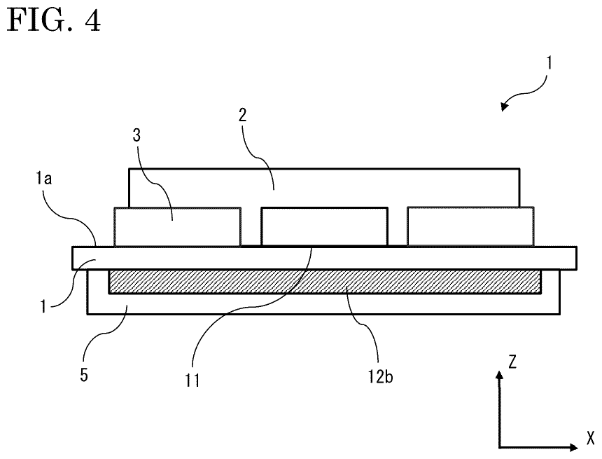

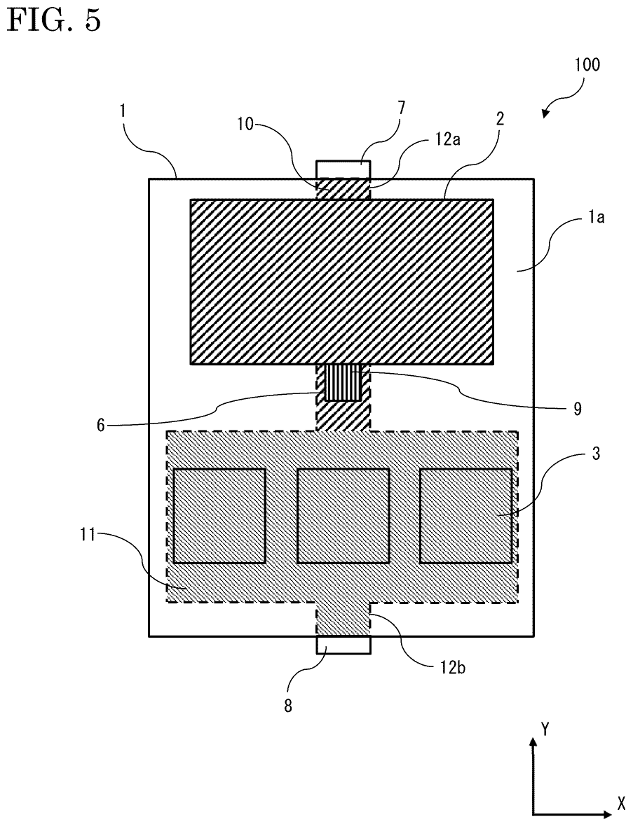

FIG. 1 is a plan view schematically showing a power conversion device 100 according to embodiment 1, and in FIG. 1, a capacitor 2 and a semiconductor module 3 are shown by only outer shapes, and a first passage 12a and a second passage 12b are shown by broken lines. FIG. 2 is a sectional view of the power conversion device 100 taken at an A-A cross-section position in FIG. 1. FIG. 3 is a sectional view of the power conversion device 100 taken at a B-B cross-section position in FIG. 1. FIG. 4 is a sectional view oof the power conversion device 100 taken at a C-C cross-section position in FIG. 1. FIG. 5 is a plan view schematically showing another power conversion device 100 according to embodiment 1, and in FIG. 5, the capacitor 2 and the semiconductor module 3 are shown by only outer shapes, and the first passage 12a and the second passage 12b are shown by broken lines. The power conversion device 100 is a device that converts input current from DC to AC or from AC to DC, or converts input voltage to different voltage. In the present disclosure, the power conversion device 100 is described as an inverter that converts DC power to AC power and supplies the AC power to a driving motor of a hybrid car or an electric car. However, the power conversion device 100 is not limited to such an inverter.

### Power Conversion Device 100

The power conversion device 100 includes a cooler 1, one or a plurality of capacitors 2, one or a plurality of semiconductor modules 3 electrically connected to the capacitor 2, and one or a plurality of heat dissipation members 6. As shown in FIG. 1, in the present embodiment, the power conversion device 100 includes one capacitor 2, three semiconductor modules 3, and one heat dissipation member 6. The capacitor 2 and the semiconductor modules 3 are placed so as to be arranged on the cooler 1. The numbers of the capacitors 2, the semiconductor modules 3, and the heat dissipation members 6, and placement of the capacitors 2 and the semiconductor modules 3, are not limited thereto. The power conversion device 100 is such a device that DC power smoothed by the capacitor 2 is subjected to power conversion by the semiconductor module 3 and then is outputted to outside. In the present embodiment, the power conversion device 100 that outputs three-phase AC power is shown, and three semiconductor modules 3 are provided for respective phases. The semiconductor modules 3 for the respective phases may be integrated into one module and thus one semiconductor module 3 may be provided. In the drawings, an input portion and an output portion provided to the power conversion device 100, and a connection configuration between the capacitor 2 and the semiconductor modules 3, are not shown. Here, directions are defined. In FIG. 1, a direction in which the semiconductor modules 3 are arranged and which is parallel to a cooling surface 1a of the cooler 1 on which the capacitor 2 and the semiconductor modules 3 are provided, is defined as an X direction, a direction parallel to the cooling surface 1a of the cooler 1 and perpendicular to the X direction is defined as a Y direction, and a direction perpendicular to the X direction and the Y direction is defined as a Z direction. In the drawings, a direction indicated by an arrow is defined as one side, and a direction opposite to the direction indicated by the arrow is defined as another side.

As shown in FIG. 3, the cooler 1 includes the first passage 12a, the second passage 12b, a coolant inlet 7 through which a coolant is supplied to the first passage 12a, and a coolant outlet 8 through which the coolant is discharged from the second passage 12b. The coolant supplied from the coolant inlet 7 flows through the first passage 12a and the second passage 12b in this order and then is discharged from the coolant outlet 8. The direction in which the coolant flows is from the one side in the Y direction to the other side in the Y direction. The coolant inlet 7 and the coolant outlet 8 are portions coupled with a device for circulating the coolant, which is provided outside. The first passage 12a and the second passage 12b are formed by a passage forming portion 5 at a part of the cooler 1 on the side opposite to the cooling surface 1a. The passage forming portion 5 is fixed via a seal member to the part of the cooler 1 on the side opposite to the cooling surface 1a, for example. The cooler 1 is made of aluminum or an aluminum alloy, for example. Since the cooler 1 is made of aluminum or an aluminum alloy, the cooler 1 can be reduced in weight. The entirety of the cooler 1 may not necessarily be made of the same material such as aluminum, and it suffices that at least a part including a first cooling portion 10 and a second cooling portion 11 described later is made of metal having a high thermal conductivity. As the coolant, water, an ethylene glycol solution, or LLC (long life coolant) is used, for example.

As shown in FIG. 3, the capacitor 2 includes a capacitor element 2a for smoothing DC power. As the capacitor element 2a, a winding film capacitor is used, for example. The capacitor element 2a is sealed by resin which is an insulating member, for example. In the present embodiment, the capacitor 2 is thermally connected to the cooling surface 1a that the cooler 1 has. Placement of the capacitor 2 is not limited thereto, and the capacitor 2 may be placed at any position as long as a connection portion 9 described later is thermally connected to the first cooling portion 10. Since the capacitor 2 is thermally connected to the cooling surface 1a, a support member for fixation provided between the capacitor 2 and the cooler 1 is not needed and therefore productivity of the power conversion device 100 can be improved. When the capacitor 2 is thermally connected to the cooling surface 1a, the capacitor 2 is fixed to the cooling surface 1a by screwing via a thermally conductive member such as a heat dissipation sheet or grease, for example. Providing the thermally conductive member can improve cooling efficiency for the capacitor 2.

The heat dissipation member 6 includes a body portion 6a1 which is a part integrated with the capacitor 2, and one or a plurality of connection portions 9 exposed from the capacitor. The heat dissipation member 6 is made of copper which is a metal material having a high thermal conductivity, for example. In the present embodiment, the body portion 6a1 of the heat dissipation member 6 is formed in a plate shape, and is opposed to a side surface of the capacitor element 2a via resin. The body portion 6a1 and the capacitor element 2a are thermally connected. In the present embodiment, the heat dissipation member 6 includes one connection portion 9, but the number of the connection portions 9 is not limited thereto.

### Cooling Structure

A cooling structure of the power conversion device 100 will be described. The cooling structure that the power conversion device 100 has is formed by the cooler 1 and the heat dissipation member 6. The one or plurality of connection portions 9 are thermally connected to the first cooling portion 10 which is a part of the cooling surface 1a made of metal, of the cooler 1, opposed to the first passage 12a. In the present embodiment, as shown in FIG. 1, since one connection portion 9 is provided, the one connection portion 9 is thermally connected to the first cooling portion 10. The connection portion 9 is connected to the first cooling portion 10 via solder or welding, for example. Connection of the connection portion 9 to the first cooling portion 10 is not limited thereto, and the connection portion 9 may be connected by screwing to the first cooling portion 10 via a thermally conductive member. The one or plurality of semiconductor modules 3 are thermally connected to the second cooling portion 11 which is a part of the cooling surface 1a made of metal, of the cooler 1, opposed to the second passage 12b. In the present embodiment, since three semiconductor modules 3 are provided, the three semiconductor modules 3 are thermally connected to the second cooling portion 11. The semiconductor modules 3 are fixed to the second cooling portion 11 by screwing via a thermally conductive member such as a heat dissipation sheet or grease, for example. Providing the thermally conductive member can improve cooling efficiency for the semiconductor modules 3. A fixation method for the semiconductor modules 3 is not limited thereto, and the semiconductor modules 3 may be fixed to the second cooling portion 11 via solder.

A first sectional area which is a sectional area perpendicular to a flow direction in a part of the first passage 12a directly under the one or plurality of connection portions 9 is smaller than a second sectional area which is a sectional area perpendicular to a flow direction in a part of the second passage 12b directly under the one or plurality of semiconductor modules 3. In the present embodiment, since one connection portion 9 is provided, the sectional area of the first passage 12a directly under the one connection portion 9 shown in FIG. 2 is the first sectional area. In the present embodiment, since three semiconductor modules 3 are provided, the sectional area of the second passage 12b directly under the three semiconductor modules 3 shown in FIG. 4 is the second sectional area.

The capacitor 2 and the semiconductor modules 3 are members that generate heat during operation of the power conversion device 100. Cooling routes for the capacitor 2 and the semiconductor modules 3 in the cooling structure that the power conversion device 100 has will be described. In the present embodiment, the capacitor 2 includes two cooling routes. The first cooling route which is the first one of the cooling routes is such a route that heat of the capacitor element 2a is dissipated via the body portion 6a1 of the heat dissipation member 6, the connection portion 9, and the first cooling portion 10 of the cooling surface 1a to the coolant flowing in the first passage 12a, as shown by an arrow C1 in FIG. 3. The second cooling route which is the second one of the cooling routes is such a route that heat of the capacitor element 2a is dissipated via the first cooling portion 10 to the coolant flowing in the first passage 12a, as shown by an arrow C2 in FIG. 3. The cooling route for the semiconductor modules 3 is such a route that heat of the semiconductor modules 3 is dissipated via the second cooling portion 11 to the coolant flowing in the second passage 12b, as shown by an arrow C3 in FIG. 3. In order to efficiently dissipate heat of the semiconductor modules 3 to the coolant, a plurality of heat dissipation fins may be formed at least at a part of the second passage 12b.

In a case where the connection portion 9 is connected to a cooling surface 1a part other than the first cooling portion 10, the distance of the first cooling route increases, so that cooling efficiency for the capacitor 2 is deteriorated. Since the connection portion 9 is thermally connected to the first cooling portion 10, the first cooling route can be shortened, whereby cooling efficiency for the capacitor 2 can be improved. Since cooling efficiency for the capacitor 2 can be improved, the capacitor 2 can be reduced in size. Since the capacitor 2 is reduced in size, the power conversion device 100 can be reduced in size. Similarly, since the semiconductor modules 3 are thermally connected to the second cooling portion 11, the cooling route for the semiconductor modules 3 can be shortened, whereby cooling efficiency for the semiconductor modules 3 can be improved.

Since the first sectional area is smaller than the second sectional area, the flow rate of the coolant increases in the first sectional area region of the first passage 12a, whereby cooling efficiency for the connection portion 9 can be improved. Since cooling efficiency for the connection portion 9 is improved, cooling efficiency for the capacitor 2 can be improved. In addition, since the first sectional area is smaller than the second sectional area, the volume of a part of the passage forming portion 5 that forms the first passage 12a can be reduced, whereby the power conversion device 100 that has a cooling structure having improved cooling efficiency for the capacitor 2 while suppressing increase in weight can be provided.

As a method for reducing the sectional area of the first passage 12a, the width of the first passage 12a in the X direction in FIG. 1 may be reduced or the height of the first passage 12a in the Z direction in FIG. 3 may be reduced. The method of reducing the width of the first passage 12a in the X direction shown in FIG. 1 can reduce the volume of the passage forming portion 5 more and therefore is more effective for reducing the weight of the cooling structure of the power conversion device 100.

### Modification

A modification of the power conversion device 100 will be described with reference to FIG. 5. In the modification shown in FIG. 5, a part where the first passage 12a is provided is different from that in the power conversion device 100 shown in FIG. 1. Since it suffices that the first sectional area directly under the connection portion 9 is smaller than the second sectional area, as shown in FIG. 5, the first passage 12a may be provided so as to overlap the entire part of the capacitor 2 as seen in the Z direction. In this configuration, the volume of the passage forming portion 5 increases but the second cooling route increases, whereby cooling efficiency for the capacitor 2 can be improved.

As described above, the power conversion device 100 according to embodiment 1 includes: the cooler 1 in which the coolant flows through the first passage 12a and the second passage 12b in this order; the one or plurality of capacitors 2; the one or plurality of semiconductor modules 3; and the one or plurality of heat dissipation members 6 including a part integrated with the capacitors 2, and the one or plurality of connection portions 9 exposed from the capacitors 2. The one or plurality of connection portions 9 are thermally connected to the first cooling portion 10 which is a part of the cooling surface 1a made of metal, of the cooler 1, opposed to the first passage 12a. The one or plurality of semiconductor modules 3 are thermally connected to the second cooling portion 11 which is a part of the cooling surface 1a made of metal, of the cooler 1, opposed to the second passage 12b. The first sectional area which is a sectional area perpendicular to the flow direction in a part of the first passage 12a directly under the one or plurality of connection portions 9 is smaller than the second sectional area which is a sectional area perpendicular to the flow direction in a part of the second passage 12b directly under the one or plurality of semiconductor modules 3. Thus, the volume of a part of the passage forming portion 5 that forms the first passage 12a in the cooler 1 can be reduced, whereby increase in the weight of the cooling structure can be suppressed. In addition, since the first sectional area is smaller than the second sectional area, the flow rate of the coolant in the first sectional area region of the first passage 12a increases, whereby cooling efficiency for the connection portion 9 can be improved. Since cooling efficiency for the connection portion 9 is improved, cooling efficiency for the capacitors 2 can be improved.

### Embodiment 2

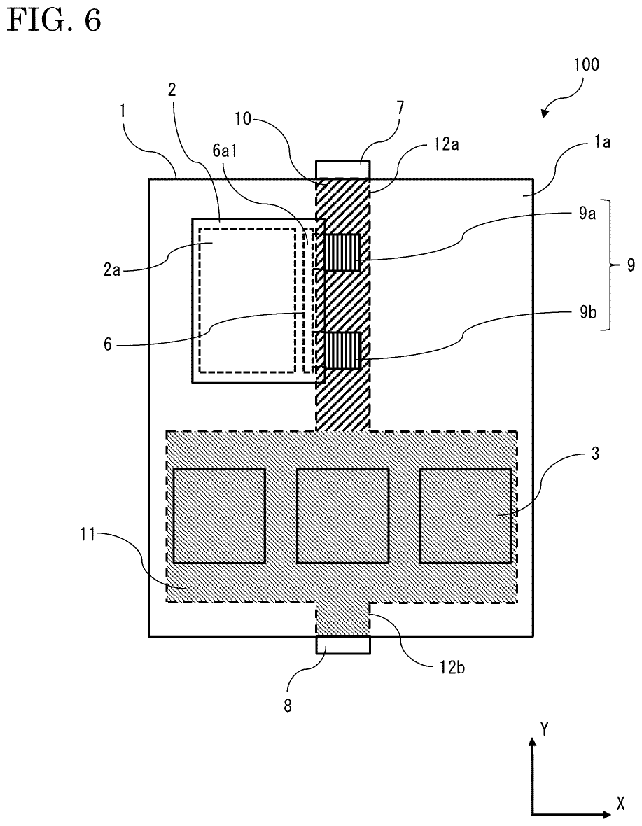

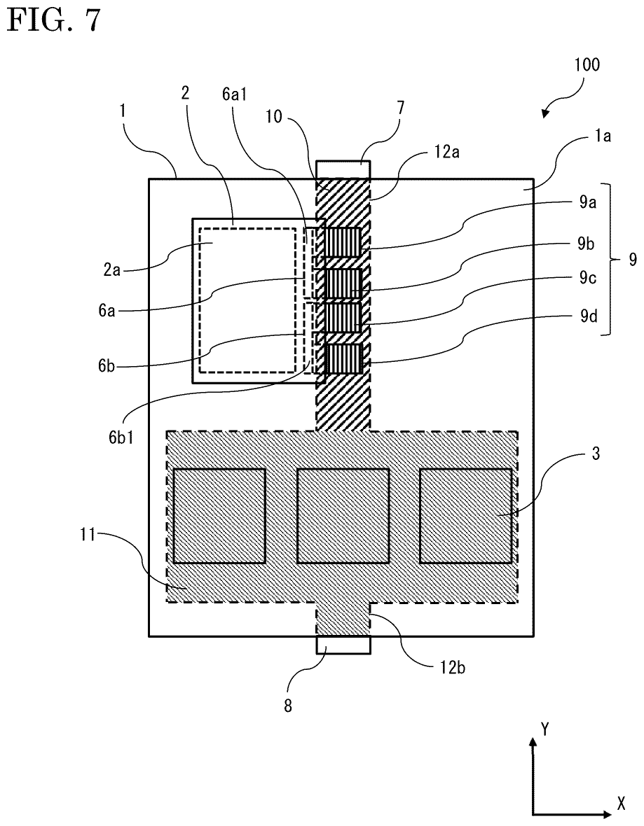

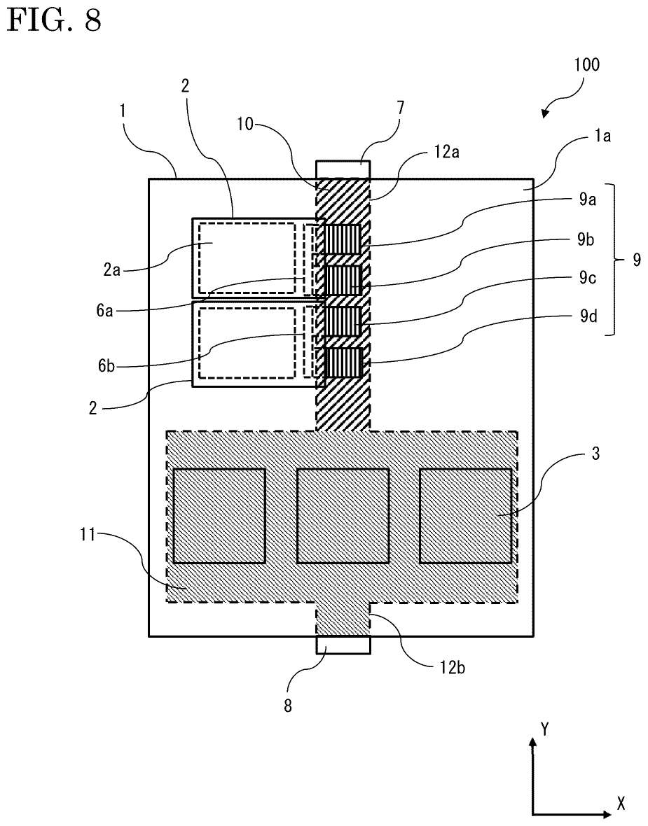

A power conversion device 100 according to embodiment 2 will be described. FIG. 6 is a plan view schematically showing the power conversion device 100 according to embodiment 2. FIG. 7 is a plan view schematically showing another power conversion device 100 according to embodiment 2. FIG. 8 is a plan view schematically showing still another power conversion device 100 according to embodiment 2. In FIG. 6, FIG. 7, and FIG. 8, the capacitor 2 and the semiconductor module 3 are shown by only outer shapes, and the first passage 12a, the second passage 12b, and the schematic configuration of the inside of the capacitor 2 are shown by broken lines. In the power conversion device 100 according to embodiment 2, a plurality of connection portions 9 are provided.

In the present embodiment, a plurality of connection portions 9 are provided. The power conversion device 100 shown in FIG. 6 includes one heat dissipation member 6, and the one heat dissipation member 6 includes the body portion 6a1 and two connection portions 9a and 9b. The power conversion device 100 shown in FIG. 7 includes two heat dissipation members 6a and 6b, the heat dissipation member 6a includes the body portion 6a1 and two connection portions 9a and 9b, and the heat dissipation member 6b includes a body portion 6b1 and two connection portions 9c and 9d. The number of the heat dissipation members 6 and the number of the connection portions 9 are not limited thereto, and more connection portions 9 may be provided.

The plurality of connection portions 9 are placed so as to be arranged in series along the direction in which the coolant flows through the first passage 12a. The direction in which the coolant flows is from the one side in the Y direction to the other side in the Y direction. In the configuration shown in FIG. 6, the connection portions 9a and 9b are cooled by the coolant in the order of the connection portion 9a and then the connection portion 9b. In the configuration shown in FIG. 7, the connection portions 9a, 9b, 9c, and 9d are cooled by the coolant in the order of the connection portion 9a, the connection portion 9b, the connection portion 9c, and then the connection portion 9d.

Even in the case where the heat dissipation member 6 includes the plurality of connection portions 9, since each of the plurality of connection portions 9 is thermally connected to the first cooling portion 10, the first cooling route can be shortened, whereby cooling efficiency for the capacitor 2 can be improved. Since cooling efficiency for the capacitor 2 can be improved, the capacitor 2 can be reduced in size. Since the capacitor 2 is reduced in size, the power conversion device 100 can be reduced in size. In a case where one of the plurality of connection portions 9 is connected to a cooling surface 1a part other than the first cooling portion 10, the distance of the first cooling route increases, so that cooling efficiency for the capacitor 2 is deteriorated. Therefore, when all the plurality of connection portions 9 are thermally connected to the first cooling portion 10, cooling efficiency for the capacitor 2 can be improved.

In the configurations shown in FIG. 6 and FIG. 7, the examples in which the power conversion device 100 includes one capacitor 2 are shown, but the number of the capacitors 2 is not limited thereto. As shown in FIG. 8, two capacitors 2 may be provided. The two capacitors 2 are provided so as to be arranged in the Y direction. For the capacitor 2 provided on the one side in the Y direction, the connection portions 9a and 9b are provided, and for the capacitor 2 provided on the other side in the Y direction, the connection portions 9c and 9d are provided. Thus, even in the case where the plurality of capacitors 2 are provided, if the connection portions 9 provided respectively for the capacitors 2 are thermally connected to the first cooling portion 10, cooling efficiency for the plurality of capacitors 2 can be improved.

### Embodiment 3

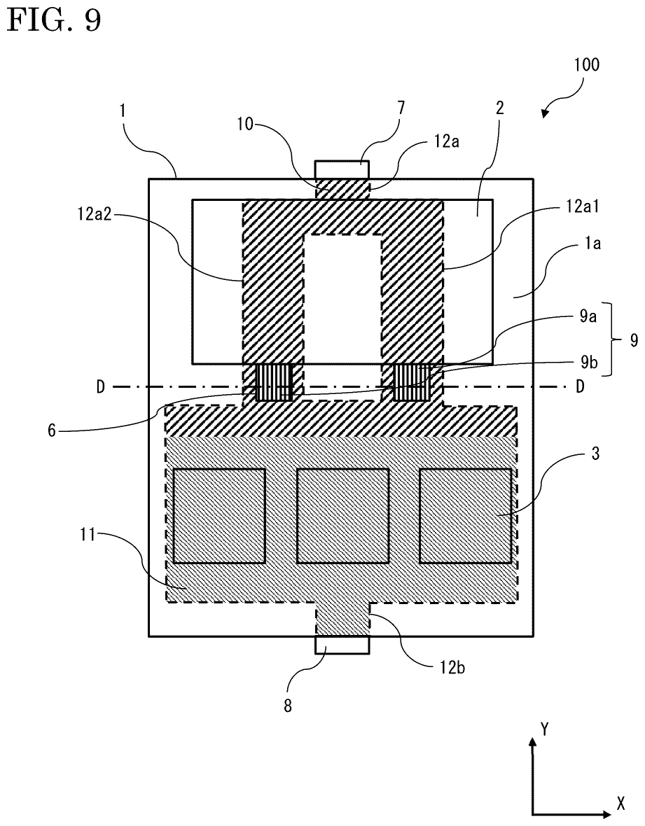

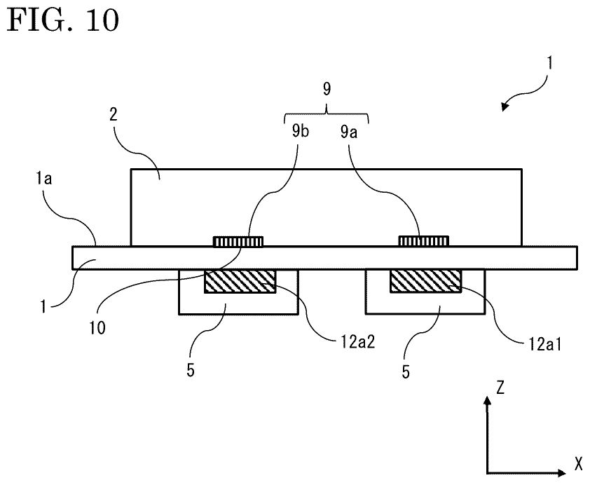

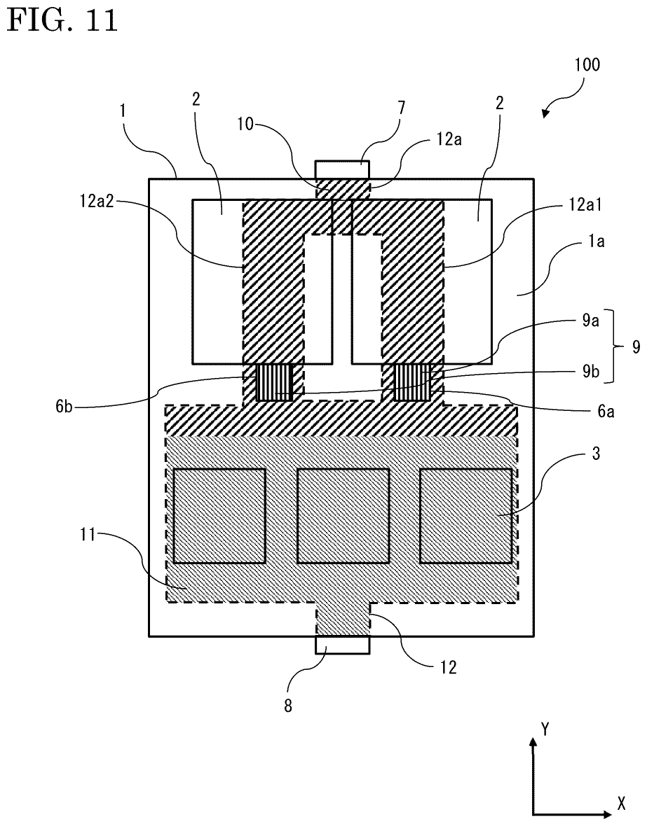

A power conversion device 100 according to embodiment 3 will be described. FIG. 9 is a plan view schematically showing the power conversion device 100 according to embodiment 3. FIG. 10 is a sectional view of the power conversion device 100 taken at a D-D cross-section position in FIG. 9. FIG. 11 is a plan view schematically showing another power conversion device 100 according to embodiment 3. In FIG. 9 and FIG. 11, the capacitor 2 and the semiconductor module 3 are shown by only outer shapes, and the first passage 12a and the second passage 12b are shown by broken lines. In the power conversion device 100 according to embodiment 3, the first passage 12a includes branch passages 12a1 and 12a2.

In the present embodiment, a plurality of connection portions 9 are provided in the power conversion device 100. The power conversion device 100 shown in FIG. 9 includes one heat dissipation member 6 (the body portion is not shown), and the one heat dissipation member 6 includes the body portion and two connection portions 9a and 9b. The power conversion device 100 shown in FIG. 11 includes two capacitors 2 placed so as to be arranged in the X direction, the capacitor 2 provided on the one side in the X direction has the heat dissipation member 6a, and the capacitor 2 provided on the other side in the X direction has the heat dissipation member 6b (their respective body portions are not shown). The heat dissipation member 6a includes one connection portion 9a, and the heat dissipation member 6b includes one connection portion 9b. The number of the capacitors 2, the number of the heat dissipation members 6, and the number of the connection portions 9 are not limited thereto, and more connection portions 9 may be provided.

The first passage 12a includes the branch passages 12a1 and 12a2 which are the same number of branched passages as the plurality of connection portions 9. In both of the power conversion devices 100 shown in FIG. 9 and FIG. 11, two connection portions 9a and 9b are provided. Therefore, the first passage 12a is branched into two passages, so that the first passage 12a includes two branch passages 12a1 and 12a2. The branch passages 12a1 and 12a2 merge on the second passage 12b side and are connected to the second passage 12b.

The plurality of connection portions 9 are respectively connected to the first cooling portions 10 respectively corresponding to the branch passages 12a1 and 12a2 which are a plurality of branch passages. As shown in FIG. 6 in embodiment 2, in a case where two connection portions 9a and 9b are placed so as to be arranged in series along the direction in which the coolant flows through the first passage 12a, the temperature of the coolant increases due to heat dissipated from the connection portion 9a placed at a position close to the coolant inlet 7. The connection portion 9b placed at a position far from the coolant inlet 7 is cooled by the coolant having an increased temperature, and therefore the temperature of the connection portion 9b becomes higher than the temperature of the connection portion 9a. Since the plurality of connection portions 9 are respectively connected to the first cooling portions 10 respectively corresponding to the branch passages 12al and 12a2, there is no connection portion 9 that is cooled by the coolant having an increased temperature, so that imbalance of cooling can be prevented from occurring among the plurality of connection portions 9. Since imbalance of cooling occurring among the plurality of connection portions 9 is suppressed, cooling efficiency for the capacitor 2 can be improved.

In the configuration shown in FIG. 9, the example in which the power conversion device 100 includes one capacitor 2 is shown. However, the number of the capacitors 2 is not limited thereto, and as shown in FIG. 11, two capacitors 2 may be provided. Even in the case where a plurality of capacitors 2 are provided as described above, if the connection portions 9 respectively provided to the capacitors 2 are thermally connected to the first cooling portions 10 respectively corresponding to the branch passages 12a1 and 12a2, cooling efficiency for each of the plurality of capacitors 2 can be improved.

In the present embodiment, for suppressing imbalance of cooling, the configuration in which one connection portion 9 is provided to each of the first cooling portions 10 respectively corresponding to the branch passages 12a1 and 12a2, is shown. However, the present disclosure is not limited thereto. Although imbalance of cooling occurs, at each of the first cooling portions 10 respectively corresponding to the branch passages 12a1 and 12a2, a plurality of connection portions 9 may be placed so as to be arranged in series along the direction in which the coolant flows through each of the branch passages 12a1 and 12a2. In this configuration, further, the plurality of connection portions 9 can be thermally connected to each first cooling portion 10, whereby cooling efficiency for the capacitor 2 can be improved.

### Embodiment 4

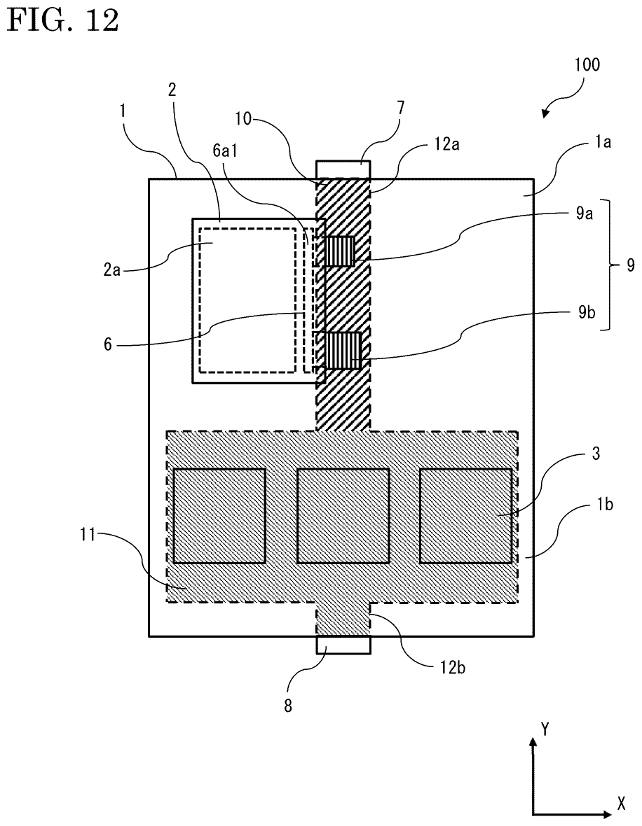

A power conversion device 100 according to embodiment 4 will be described. FIG. 12 is a plan view schematically showing the power conversion device 100 according to embodiment 4, and in FIG. 12, the capacitor 2 and the semiconductor module 3 are shown by only outer shapes, and the first passage 12a and the second passage 12b are shown by broken lines. In the power conversion device 100 according to embodiment 4, connection portions 9 having different sizes are provided.

The area of a part connected to the first cooling portion 10, of the connection portion 9 placed on the coolant inlet 7 side, is smaller than the area of a part connected to the first cooling portion 10, of the connection portion 9 placed on the second passage 12b side. The power conversion device 100 shown in FIG. 12 includes one heat dissipation member 6, and the one heat dissipation member 6 includes the body portion 6a1 and two connection portions 9a and 9b. The connection portion 9a is the connection portion 9 placed on the coolant inlet 7 side, and the connection portion 9b is the connection portion 9 placed on the second passage 12b side. The area of the part connected to the first cooling portion 10, of the connection portion 9a, is smaller than the area of the part connected to the first cooling portion 10, of the connection portion 9b. The number of the heat dissipation members 6 and the number of the connection portions 9 are not limited thereto, and more connection portions 9 may be provided. In a case where more connection portions 9 are placed so as to be arranged in series along the direction in which the coolant flows, the areas of parts connected to the first cooling portion 10, of the plurality of connection portions 9, increase along the direction in which the coolant flows.

As described above, the temperature of the coolant directly under the connection portion 9b becomes higher than the temperature of the coolant directly under the connection portion 9a. When the area of the connection portion 9b is larger, the thermal resistance between the connection portion 9b and the first cooling portion 10 can be reduced. Since the thermal resistance between the connection portion 9b and the first cooling portion 10 is reduced, the cooling effect for the connection portion 9b is improved, so that the temperature of the connection portion 9b becomes low, whereby a temperature difference between the connection portion 9a and the connection portion 9b can be reduced. Since the temperature difference between the connection portion 9a and the connection portion 9b is reduced, unevenness of the temperature inside the capacitor 2 can be reduced, whereby the temperature at the maximum temperature point inside the capacitor 2 can be reduced. The life of the capacitor 2 becomes shorter when used at a higher temperature. Therefore, using the configuration shown in the present embodiment can prolong the life of the capacitor 2.

### Embodiment 5

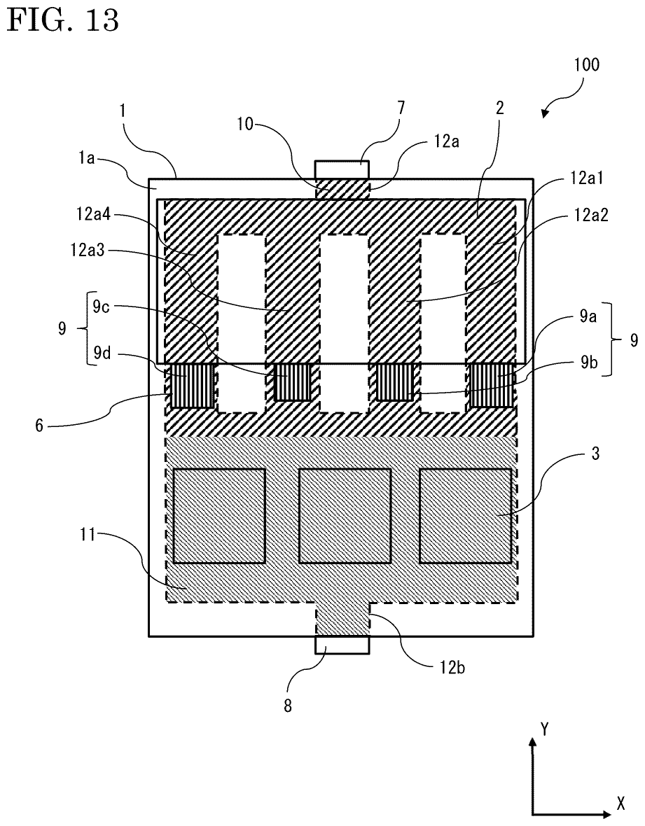

A power conversion device 100 according to embodiment 5 will be described. FIG. 13 is a plan view schematically showing the power conversion device 100 according to embodiment 5, and in FIG. 13, the capacitor 2 and the semiconductor module 3 are shown by only outer shapes, and the first passage 12a and the second passage 12b are shown by broken lines. In the power conversion device 100 according to embodiment 5, connection portions 9 having different sizes are provided.

As the distance of the first passage 12a from the coolant inlet 7 to a part of the branch passage directly under the connection portion 9 becomes longer, the area of a part of the connection portion 9 connected to the first cooling portion 10 becomes larger. The power conversion device 100 shown in FIG. 13 includes one heat dissipation member 6 (the body portion is not shown), and the one heat dissipation member 6 includes the body portion and four connection portions 9a, 9b, 9c, and 9d. The areas of the connection portions 9a and 9d are larger than the areas of the connection portions 9b and 9c. The areas of the connection portions 9a and 9d are equal to each other, and the areas of the connection portions 9b and 9c are also equal to each other. Since the power conversion device 100 includes the four connection portions 9a, 9b, 9c, and 9d, the first passage 12a is branched into four passages, so that the first passage 12a includes four branch passages 12a1, 12a2, 12a3, and 12a4. The branch passages 12a1, 12a2, 12a3, and 12a4 merge on the second passage 12b side and are connected to the second passage 12b.

A distance (hereinafter, referred to as branch distance) of the first passage 12a from the coolant inlet 7 to a branch passage part directly under the connection portion 9 may be different among the branch passages. In the present embodiment, the branch distances of the branch passages 12a1 and 12a4 are greater than the branch distances of the branch passages 12a2 and 12a3. The branch distances of the branch passages 12a1 and 12a4 are equal to each other, and the branch distances of the branch passages 12a2 and 12a3 are also equal to each other. In a case where the branch distance is long, the resistance of the passage in the branch passage increases, so that the flow volume of the coolant flowing through the branch passage per unit time is reduced. When the flow volume of the coolant is reduced, the thermal resistance of the connection portion 9 increases. Therefore, the temperatures of the connection portions 9a and 9d having long branch distances become higher than the temperatures of the connection portions 9b and 9c having short branch distances. The temperature inside the capacitor 2 becomes higher at positions close to the connection portions 9a and 9d.

When the areas of the connection portions 9a and 9d are larger, the thermal resistance between the first cooling portion 10 and each of the connection portions 9a and 9d can be reduced. Since the thermal resistance between the first cooling portion 10 and each of the connection portions 9a and 9d is reduced, the cooling effect for the connection portions 9a and 9d is improved, so that the temperatures of the connection portions 9a and 9d become low, whereby temperature differences between the connection portions 9b and 9c and the connection portions 9a and 9d can be reduced. Since the temperature differences between the connection portions 9b and 9c and the connection portions 9a and 9d are reduced, unevenness of the temperature inside the capacitor 2 can be reduced, whereby the temperature at the maximum temperature point inside the capacitor 2 can be reduced. The life of the capacitor 2 becomes shorter when used at a higher temperature. Therefore, using the configuration shown in the present embodiment can prolong the life of the capacitor 2.

### Embodiment 6

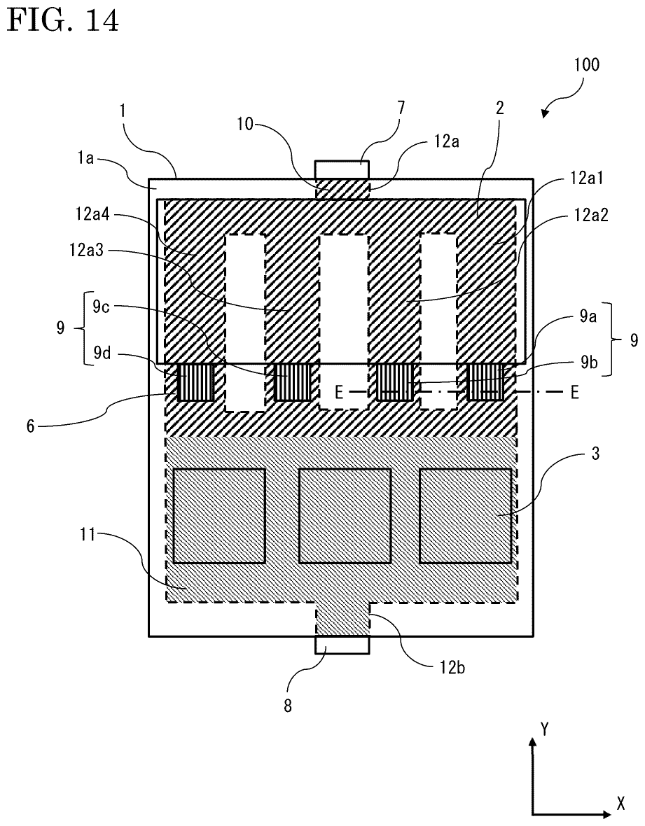

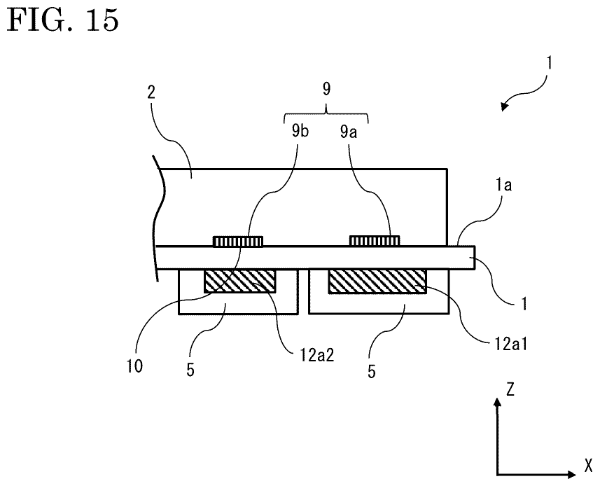

A power conversion device 100 according to embodiment 6 will be described. FIG. 14 is a plan view schematically showing the power conversion device 100 according to embodiment 6, and in FIG. 14, the capacitor 2 and the semiconductor module 3 are shown by only outer shapes, and the first passage 12a and the second passage 12b are shown by broken lines. FIG. 15 is a sectional view of the power conversion device 100 taken at an E-E cross-section position in FIG. 14. In the power conversion device 100 according to embodiment 6, the first sectional areas have different sizes among branch passages.

As the distance of the first passage 12a from the coolant inlet 7 to a part of the branch passage directly under the connection portion 9 becomes longer, the first sectional area becomes larger. The power conversion device 100 shown in FIG. 14 includes one heat dissipation member 6 (the body portion is not shown), and one heat dissipation member 6 includes the body portion and four connection portions 9a, 9b, 9c, and 9d. The sizes of the connection portions 9a, 9b, 9c, and 9d are the same. Since the power conversion device 100 includes the four connection portions 9a, 9b, 9c, and 9d, the first passage 12a is branched into four passages, so that the first passage 12a includes four branch passages 12a1, 12a2, 12a3, and 12a4. The branch passages 12a1, 12a2, 12a3, and 12a4 merge on the second passage 12b side and are connected to the second passage 12b.

In the configuration of the branch passages shown in FIG. 14, the branch distances of the branch passages 12a1 and 12a4 are greater than the branch distances of the branch passages 12a2 and 12a3. The branch distances of the branch passages 12a1 and 12a4 are equal to each other, and the branch distances of the branch passages 12a2 and 12a3 are also equal to each other. In a case where the branch distance is long, the resistance of the passage in the branch passage increases, so that the flow volume of the coolant flowing through the branch passage per unit time is reduced. When the flow volume of the coolant is reduced, the thermal resistance of the connection portion 9 increases. In the present embodiment, for reducing the resistances of the passages in the branch passages, the first sectional areas of the branch passages 12a1 and 12a4 having long branch distances are set to be larger than the first sectional areas of the branch passages 12a2 and 12a3 having short branch distances.

When the first sectional areas are larger, increase in the thermal resistances at the connection portions 9a and 9d can be suppressed. Since increase in the thermal resistances at the connection portions 9a and 9d are suppressed, the cooling effect for the connection portions 9a and 9d is improved, so that the temperatures of the connection portions 9a and 9d become low, whereby temperature differences between the connection portions 9b and 9c and the connection portions 9a and 9d can be reduced. Since the temperature differences between the connection portions 9b and 9c and the connection portions 9a and 9d are reduced, unevenness of the temperature inside the capacitor 2 can be reduced, whereby the temperature at the maximum temperature point inside the capacitor 2 can be reduced. The life of the capacitor 2 becomes shorter when used at a higher temperature. Therefore, using the configuration shown in the present embodiment can prolong the life of the capacitor 2.

### Embodiment 7

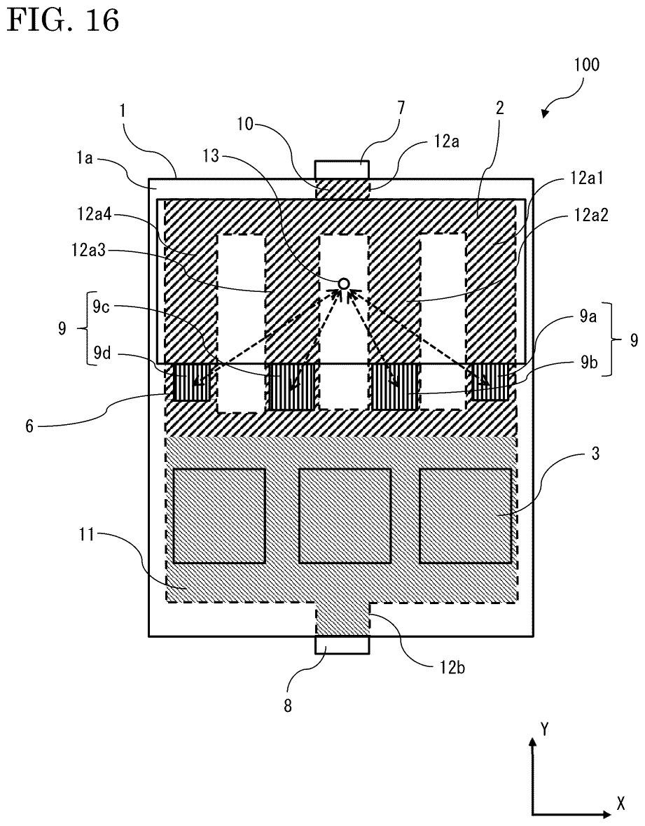

A power conversion device 100 according to embodiment 7 will be described. FIG. 16 is a plan view schematically showing the power conversion device 100 according to embodiment 7, and in FIG. 16, the capacitor 2 and the semiconductor module 3 are shown by only outer shapes, and the first passage 12a and the second passage 12b are shown by broken lines. In the power conversion device 100 according to embodiment 7, connection portions 9 having different sizes are provided.

A part where the temperature becomes highest in the capacitor 2 is defined as a maximum temperature portion of the capacitor. In FIG. 16, a maximum temperature portion 13 of the capacitor as seen from the one side in the Z direction is indicated by a white circle. In the present embodiment, the maximum temperature portion 13 of the capacitor is placed near the center of the capacitor 2, but the location of the maximum temperature portion 13 of the capacitor is not limited thereto.

As a distance (hereinafter, referred to as connection portion distance; connection portion distances are shown by broken line arrows in FIG. 16) from the maximum temperature portion 13 of the capacitor to the center part of the connection portion 9 becomes shorter, the area of a part connected to the first cooling portion 10, of the connection portion 9, becomes larger. The configuration of the branch passages shown in FIG. 16 is the same as the configuration of the branch passages shown in FIG. 13. In the present embodiment, the connection portion distances of the connection portions 9a and 9d are greater than the connection portion distances of the connection portions 9b and 9c. The connection portion distances of the connection portions 9a and 9d are equal to each other, and the connection portion distances of the connection portions 9b and 9c are also equal to each other. In a case where the connection portion distance is short, the maximum temperature portion 13 of the capacitor is at a close position, so that the thermal resistances of the connection portions 9b and 9c increase. Therefore, the temperatures of the connection portions 9b and 9c having short connection portion distances become higher than the temperatures of the connection portions 9a and 9d having long connection portion distances.

In the present embodiment, the areas of the connection portions 9b and 9c are set to be larger than the areas of the connection portions 9b and 9c having long connection portion distances. When the areas of the connection portions 9b and 9c are larger, the thermal resistance between the first cooling portion 10 and each of the connection portions 9b and 9c can be reduced. Since the thermal resistance between the first cooling portion 10 and each of the connection portions 9b and 9c is reduced, the cooling effect for the connection portions 9b and 9c is improved, so that the temperatures of the connection portions 9b and 9c become low, whereby the temperature of the maximum temperature portion 13 of the capacitor can be reduced. The life of the capacitor 2 becomes shorter when used at a higher temperature. Therefore, using the configuration shown in the present embodiment can prolong the life of the capacitor 2.

In the present embodiment, the connection portion distances of the connection portions 9a and 9d are equal to each other, and the connection portion distances of the connection portions 9b and 9c are equal to each other. Therefore, the areas of the connection portions 9b and 9c are set to be larger than the areas of the connection portions 9b and 9c. The areas of the connection portions 9 are not limited to two kinds. The above effect can be obtained if the area of the connection portion 9 becomes larger as the connection portion distance becomes shorter. In accordance with the number of provided connection portions 9, the area connected to the first cooling portion 10, of each of the connection portions 9, may be adjusted. By finely adjusting the areas of the connection portions 9 as described above, a heat dissipation structure in which unevenness of the temperature inside the capacitor 2 is reduced is obtained, while temperature increase at the maximum temperature portion 13 of the capacitor can be suppressed.

### Embodiment 8

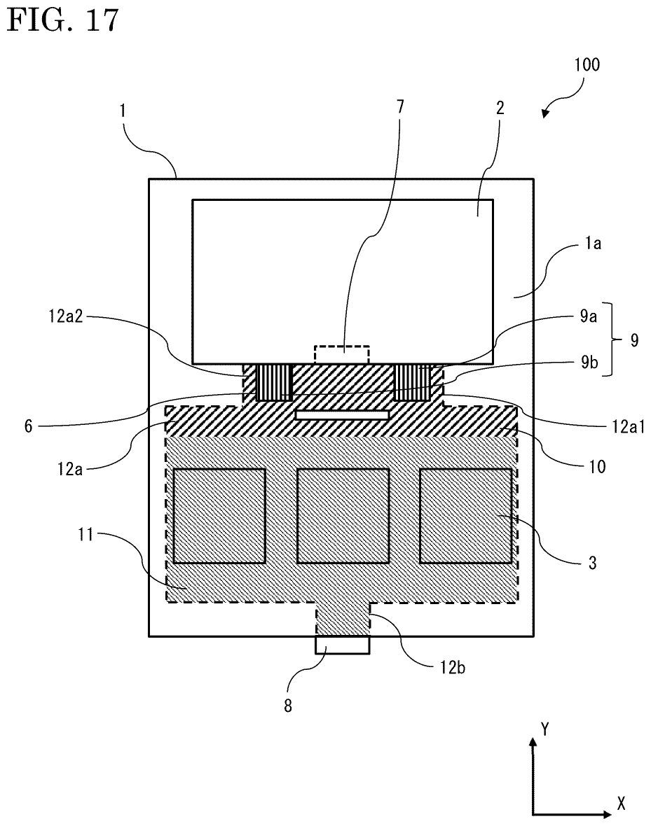

A power conversion device 100 according to embodiment 8 will be described. FIG. 17 is a plan view schematically showing the power conversion device 100 according to embodiment 8, and in FIG. 17, the capacitor 2 and the semiconductor module 3 are shown by only outer shapes, and the first passage 12a and the second passage 12b are shown by broken lines. In the power conversion device 100 according to embodiment 8, placement of the first cooling portion 10 directly under the capacitor 2 is different from that in the above embodiments.

The connection portion 9 is connected to the first cooling portion 10 provided between the capacitor 2 and the semiconductor modules 3, and the first cooling portion 10 is not provided at a part of the cooler 1 where the capacitor 2 is placed. The power conversion device 100 shown in FIG. 17 includes one heat dissipation member 6 (the body portion is not shown), and the one heat dissipation member 6 includes the body portion and two connection portions 9a and 9b. The sizes of the connection portions 9a and 9b are the same. Since the power conversion device 100 includes the two connection portions 9a and 9b, the first passage 12a is branched into two passages, and the first passage 12a includes two branch passages 12a1 and 12a2. The branch passages 12a1 and 12a2 merge on the second passage 12b side and are connected to the second passage 12b.

Since the first cooling portion 10 is not provided at the part of the cooler 1 where the capacitor 2 is placed, the passage forming portion 5 is not provided at a part of the cooler 1 on the other side in the Z direction of the capacitor 2, and the coolant inlet 7 is provided at the part. In this configuration, while the capacitor 2 is efficiently cooled, the size of the first cooling portion 10 can be minimized, whereby the volume of the passage forming portion 5 can be minimized. Since the volume of the passage forming portion 5 is reduced, increase in the weight of the cooling structure of the power conversion device 100 can be suppressed.

### Embodiment 9

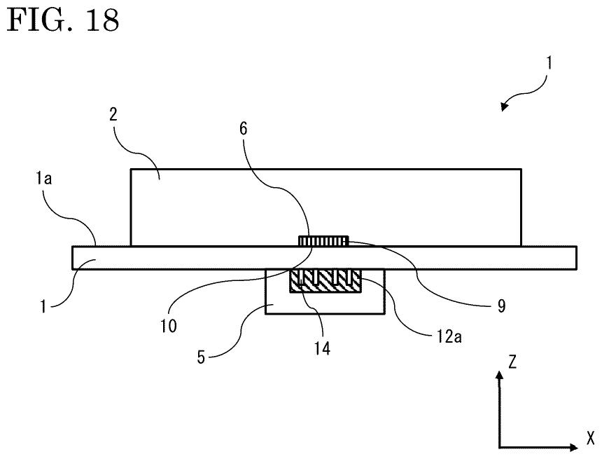

A power conversion device 100 according to embodiment 9 will be described. FIG. 18 is a sectional view schematically showing the power conversion device 100 according to embodiment 9 in a state where the power conversion device 100 is cut at a position equivalent to that in FIG. 2. In the power conversion device 100 according to embodiment 9, fins 14 are provided in addition to the configuration shown in embodiment 1.

A plurality of fins 14 are formed at least at a part of the first passage 12a. In the present embodiment, as shown in FIG. 18, four fins 14 are formed so as to be arranged in the X direction at a part of the first passage 12a on the side opposite to the first cooling portion 10 of the cooler 1. The number of the fins 14 is not limited thereto, and the number of the fins 14 may be increased in the X direction, or the fins 14 may be provided in a plurality of rows in the Y direction. The fins 14 may be formed integrally with the cooler 1, for example.

In this configuration, the thermal resistance at a part of the cooler 1 where the first cooling portion 10 is provided can be reduced, whereby the capacitor 2 can be efficiently cooled. It is desirable that the fins 14 are formed at a part of the first passage 12a directly under the first cooling portion 10 to which the connection portion 9 is connected, as shown in FIG. 18. Since the thermal resistance at a part of the cooler 1 between the connection portion 9 and the first passage 12a is reduced, the capacitor 2 can be cooled more efficiently via the connection portion 9.

### Embodiment 10

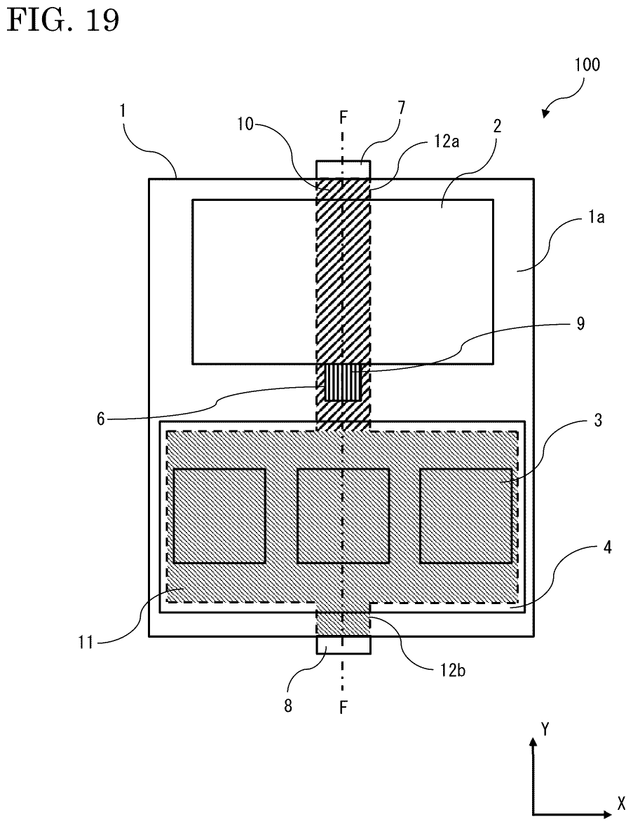

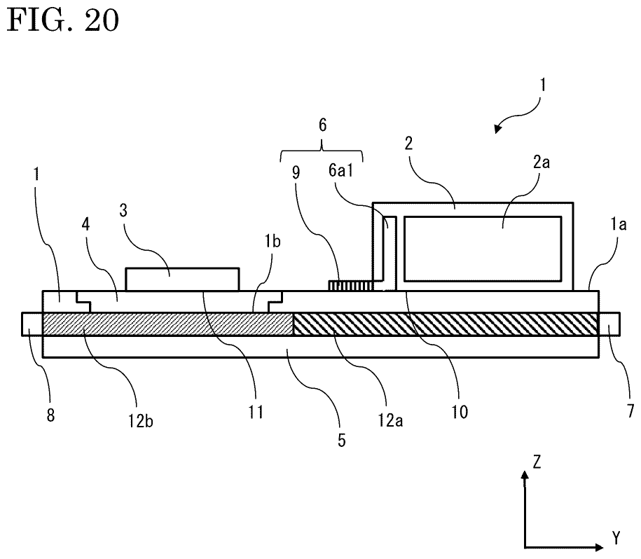

A power conversion device 100 according to embodiment 10 will be described. FIG. 19 is a plan view schematically showing the power conversion device 100 according to embodiment 10, and in FIG. 19, the capacitor 2 and the semiconductor module 3 are shown by only outer shapes, and the first passage 12a and the second passage 12b are shown by broken lines. FIG. 20 is a sectional view of the power conversion device 100 taken at an F-F cross-section position in FIG. 19. In the power conversion device 100 according to embodiment 10, the cooler 1 includes an opening 1b and a lid 4.

As shown in FIG. 20, the cooler 1 includes the opening 1b from which the second passage 12b is exposed, and the lid 4 covering the opening 1b. The second cooling portion 11 is provided at a part of the lid 4 on the side opposite to the second passage 12b side. Since the second cooling portion 11 is provided at the lid 4, as shown in FIG. 19, the semiconductor module 3 is connected to the lid 4. The lid 4 is provided on a side of the cooler 1 where the cooling surface 1a is provided. The lid 4 is fixed to a part of the cooler 1 around the opening 1b via a seal member (not shown), for example.

In the configuration in which the lid 4 is not provided as shown in embodiment 1, since the lid 4 is not needed, the number of components of the power conversion device 100 can be decreased. Since the number of components of the power conversion device 100 is decreased, the assembly time for the power conversion device 100 can be shortened, whereby productivity of the power conversion device 100 can be improved. In addition, since a structure for preventing leakage of the coolant by a seal member or the like is not needed, reliability of the second passage 12b can be improved.

In the configuration of the present embodiment in which the lid 4 is provided, the semiconductor module 3 is connected to the lid 4, and therefore, when a malfunction occurs in the semiconductor module 3, the semiconductor module 3 and the lid 4 can be detached from the body part of the cooler 1. Since only the semiconductor module 3 and the lid 4 can be detached from the cooler 1, normal components other than the semiconductor module 3 and the lid 4 can be reused. In a case where a malfunction occurs in the semiconductor module 3 in a configuration in which the lid 4 is not provided, the entirety of the power conversion device 100 is to be discarded. Since the entirety of the power conversion device 100 is discarded, normal components of the power conversion device 100 cannot be used, so that productivity of the power conversion device 100 is deteriorated.

### Embodiment 11

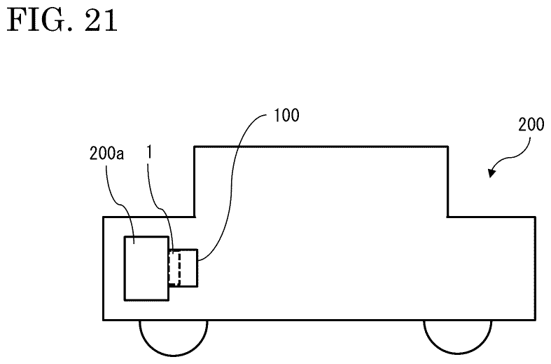

A power conversion device 100 according to embodiment 11 will be described. FIG. 21 shows an example of a placement state of the power conversion device 100 according to embodiment 11. The power conversion device 100 according to embodiment 11 is provided to an electric vehicle 200.

As shown in FIG. 21, the power conversion device 100 is provided to the electric vehicle 200. The electric vehicle 200 may be any of an electric car (BEV: Battery Electric Vehicle), a hybrid car (HEV: Hybrid Electric Vehicle), a plug-in hybrid car (PHEV: Plug-in Hybrid Electric Vehicle), and a fuel cell car (FCEV: Fuel Cell Electric Vehicle). In the power conversion device 100, for example, a cooler 1 part of the power conversion device 100 is fixed to a motor 200a. In FIG. 21, the cooler 1 is a part shown by a broken line.

Needs in the market for the electric vehicle 200 include torque increase. When torque of the electric vehicle 200 is increased, current flowing through the power conversion device 100 increases, so that the heat generation amount of the capacitor 2 increases. In addition, in order to extend the cruising distance during traveling using the motor 200a, the power conversion device 100 needs to be reduced in weight. The power conversion device 100 according to the present disclosure has a cooling structure having improved cooling efficiency for the capacitor 2 while suppressing increase in weight. By providing the power conversion device 100 according to the present disclosure to the electric vehicle 200, great torque and extension of the cruising distance can be both achieved, whereby the value of the electric vehicle 200 can be improved.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 cooler
1a cooling surface
1b opening
2 capacitor
2a capacitor element
3 semiconductor module
4 lid
5 passage forming portion
6, 6a, 6b heat dissipation member
6a1, 6b1 body portion
7 coolant inlet
8 coolant outlet
9, 9a, 9b, 9c, 9d connection portion
10 first cooling portion
11 second cooling portion
12a first passage
12a1, 12a2, 12a3, 12a4 branch passage
12b second passage
13 maximum temperature portion of capacitor
14 fin
100 power conversion device
200 electric vehicle
200a motor

1. A power conversion device comprising:
a cooler including a first passage, a second passage, a coolant inlet through which a coolant is supplied to the first passage, and a coolant outlet through which the coolant is discharged from the second passage, such that the coolant supplied from the coolant inlet flows through the first passage and the second passage in this order and then is discharged from the coolant outlet;
one or a plurality of capacitors;
one or a plurality of semiconductor modules electrically connected to the capacitors; and
one or a plurality of heat dissipation members including a part integrated with the capacitors, and one or a plurality of connection portions exposed from the capacitors, wherein
the one or plurality of connection portions are thermally connected to a first cooling portion which is a part of a cooling surface made of metal, of the cooler, opposed to the first passage,
the one or plurality of semiconductor modules are thermally connected to a second cooling portion which is a part of the cooling surface made of metal, of the cooler, opposed to the second passage, and
a first sectional area which is a sectional area perpendicular to a flow direction in a part of the first passage directly under the one or plurality of connection portions is smaller than a second sectional area which is a sectional area perpendicular to a flow direction in a part of the second passage directly under the one or plurality of semiconductor modules.

2. The power conversion device according to claim 1, wherein
the plurality of connection portions are provided, and
the plurality of connection portions are placed so as to be arranged in series along a direction in which the coolant flows through the first passage.

3. The power conversion device according to claim 1, wherein
the plurality of connection portions are provided,
the first passage includes branch passages which are the same number of branched passages as the plurality of connection portions, and
the plurality of connection portions are respectively connected to the first cooling portions respectively corresponding to the plurality of branch passages.

4. The power conversion device according to claim 2, wherein
an area of a part connected to the first cooling portion, of the connection portion placed on the coolant inlet side, is smaller than an area of a part connected to the first cooling portion, of the connection portion placed on the second passage side.

5. The power conversion device according to claim 3, wherein
as a distance of the first passage from the coolant inlet to a part of the branch passage directly under the connection portion becomes longer, an area of a part of the connection portion connected to the first cooling portion becomes larger.

6. The power conversion device according to claim 3, wherein
as a distance of the first passage from the coolant inlet to a part of the branch passage directly under the connection portion becomes longer, the first sectional area becomes larger.

7. The power conversion device according to claim 3, wherein
a part where a temperature becomes highest in the capacitor is defined as a maximum temperature portion of the capacitor, and
as a distance from the maximum temperature portion to a center part of the connection portion becomes shorter, an area of a part connected to the first cooling portion, of the connection portion, becomes larger.

8. The power conversion device according to claim 1, wherein
the capacitors and the semiconductor modules are placed so as to be arranged on the cooler,
the connection portion is connected to the first cooling portion provided between the capacitors and the semiconductor modules, and
the first cooling portion is not provided at a part of the cooler where the capacitors are placed.

9. The power conversion device according to claim 1, wherein
a plurality of fins are formed at least at a part of the first passage.

10. The power conversion device according to claim 1, wherein
the cooler includes an opening from which the second passage is exposed, and a lid covering the opening, and
the second cooling portion is provided at a part of the lid on a side opposite to the second passage side.

11. The power conversion device according to claim 1, the power conversion device being provided to an electric vehicle.
